(19) United States
(12) Patent Application Publication
(10) Pub. No.: US 2007/0076395 A1
(43) Pub. Date: Apr. 5, 2007

(54) COMPONENT-FIXING DEVICE, AND PRINTED CIRCUIT BOARD AND ELECTRONIC APPARATUS WITH COMPONENT-FIXING DEVICE

(76) Inventors: Tokihiko Mori, Kunitachi-shi (JP); Sadao Makita, Hanno-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/468,719

(22) Filed: Aug. 30, 2006

(30) Foreign Application Priority Data
Sep. 30, 2005 (JP) 2005-288004

(51) Int. Cl. H05K 7/14; H05K 7/18

(52) U.S. Cl. 361/796

(57) ABSTRACT

According to one embodiment, a component-fixing device having a flexible substrate, a positioning member and a socket unit. The flexible substrate includes a plurality of connection terminals that connect a circuit component to a printed wiring board. The positioning member holds the flexible substrate, positions the flexible substrate on the printed wiring board, and makes the flexible substrate tightly contact the printed wiring board when the flexible substrate is soldered to the printed wiring board. The socket unit secured to the printed wiring board, in place of the positioning member, holds the circuit component on the flexible substrate.

### CROSS-REFERENCE TO RELATED APPLICATION

This application is based upon and claims the benefit of priority from Japanese Patent Application No. 2005-288004, filed Sep. 30, 2005, the entire contents of which are incorporated herein by reference.

### BACKGROUND

1. Field

One embodiment of the invention relates to a component-fixing device using a socket unit, and a printed circuit board and electronic apparatus with the component-fixing device.

2. Description of the Related Art

A fixing device using a box-shaped socket unit is known as one for fixing, to a printed wiring board, a circuit component that exhibits a low resistance against thermal stress. The socket unit includes a substrate with connection terminals, and a frame member fixed to the upper portion of the substrate to surround circuit components. A ball grid array (BGA) semiconductor package, for example, is contained in the frame member. To mount a semiconductor package using the socket unit, the socket unit is firstly sent to a reflow furnace, where it is soldered to a printed wiring board. After the solder-melting process, a semiconductor package is placed on the socket unit, whereby it is mounted on the printed wiring board (see, for example, Jpn. Pat. Appln. KOKAI Publication No. 2003-69187).

The conventional socket unit is similar, in the coupling structure using solder, to the conventional BGA. Therefore, if warpage occurs on the printed wiring board, part of the socket unit will inevitably be raised, with the result that a crack may occur in the solder coupling portion, or a portion other than the contacts be short-circuited.

To avoid these problems, the socket unit may have a flexible substrate. If a flexible substrate is used as the substrate of the socket unit disclosed in Jpn. Pat. Appln. KOKAI Publication No. 2003-69187, the connection terminals can be arranged along the printed wiring board.

In the socket unit constructed as above, however, the frame member increases the thermal capacity of the portion around the frame member, therefore solder may not sufficiently be melted when the socket unit is soldered or exchanged for another. In contrast, if only the flexible substrate is mounted on the printed wiring board to avoid such problems, mounting by an automatic mounter may be impossible, and warpage may well occur in the flexible substrate (i.e., the substrate may have portions that are not reliably fixed) while solder is melted.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view illustrating a portable computer according to a first embodiment;

FIG. 2 is an exemplary perspective view illustrating part of a printed circuit board contained in the housing of the portable computer shown in FIG. 1;

FIG. 3 is an exemplary exploded view illustrating a component-fixing device incorporated in the printed circuit board shown in FIG. 2;

FIG. 4 is an exemplary sectional view illustrating the component-fixing device of the printed circuit board shown in FIG. 2;

FIG. 5 is an exemplary sectional view illustrating a connection terminal incorporated in the flexible substrate of the component-fixing device shown in FIG. 2;

FIG. 6 is another exemplary view illustrating the printed circuit board of FIG. 3;

FIG. 7 is an exemplary perspective view illustrating a positioning member and flexible substrate incorporated in the printed circuit board of FIG. 6;

FIG. 8 is an exemplary sectional view illustrating a state in which the positioning member is mounted on the printed circuit board of FIG. 6;

FIG. 9 is an exemplary sectional view useful in explaining the process of exchanging the flexible substrate using a BGA repair unit;

FIG. 10 is an exemplary sectional view illustrating a component-fixing device according to a second embodiment; and

FIG. 11 is an exemplary sectional view illustrating a connection terminal incorporated in the flexible substrate of the component-fixing device shown in FIG. 10.

### DETAILED DESCRIPTION

Various embodiments according to the invention will be described hereinafter with reference to the accompanying drawings. In general, according to one embodiment of the invention, a component-fixing device having a flexible substrate 25, a positioning member 61 and a socket unit 24, 81. The flexible substrate 25 includes a plurality of connection terminals 52, 85 that connect a circuit component 23 to a printed wiring board 21. The positioning member 61 holds the flexible substrate 25, positions the flexible substrate 25 on the printed wiring board 21, and makes the flexible substrate 25 tightly contact the printed wiring board 21 when the flexible substrate 25 is soldered to the printed wiring board 21. The socket unit 24, 81 secured to the printed wiring board 21, in place of the positioning member 61, holds the circuit component 23 on the flexible substrate 25.

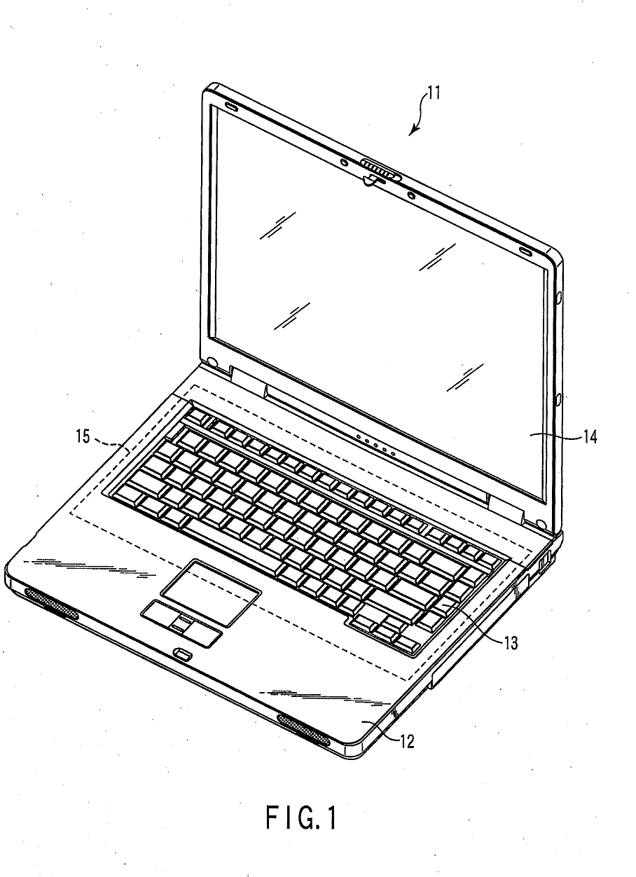

Referring first to FIGS. 1 to 5, an electronic apparatus with a component-fixing device according to a first embodiment will be described.

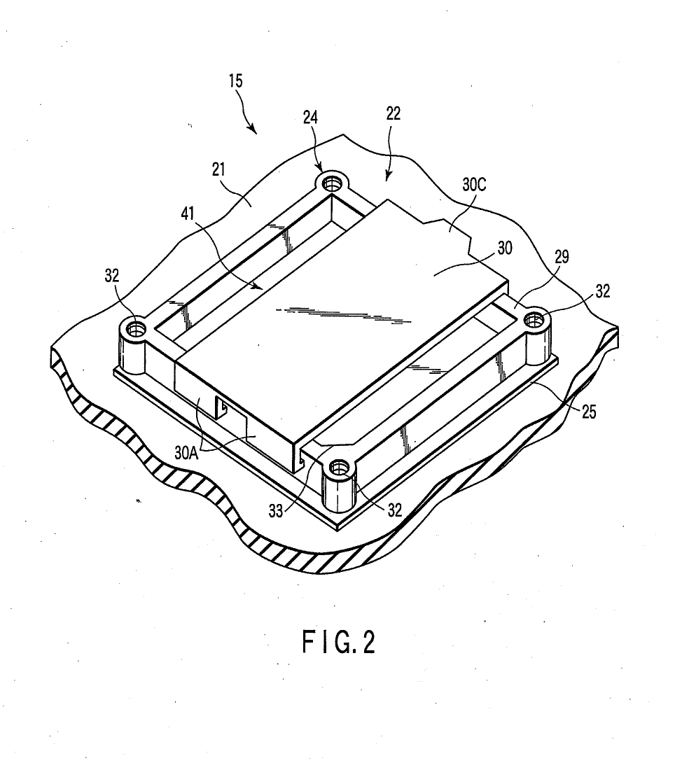

As shown in FIG. 1, a portable computer 11 as an example of the electronic apparatus comprises a housing 12, keyboard 13 and display 14. The housing 12 contains a printed circuit board 15. As can be seen from FIGS. 2 to 4, the printed circuit board 15 comprises a printed wiring board 21, component-fixing device 22 and a ball grid array (BGA) type semiconductor package 23 as an example of a circuit component. The component-fixing device 22 includes a socket unit 24 and flexible substrate 25.

The socket unit 24 includes a frame member 29 surrounding the semiconductor package 23, and a lid member 30 fixed to the frame member 29. The frame member 29 and lid member 30 are formed of an aluminum alloy having a high thermal conductivity and heat releasing property. The region surrounded by the frame member 29 receives the semiconductor package 23.

The frame member 29 has four lateral holes 31 for securing the lid member 30. The frame member 29 has four screw holes 32 at the four corners thereof. The frame member 29 is screwed to the printed circuit board 21 by screws fitted in the screw holes 32. The flexible substrate 25 is held between the frame member 29 of the socket unit 24 and the printed circuit board 21. Namely, the frame member 29 and printed circuit board 21 are located at the opposite sides of the flexible substrate 25.

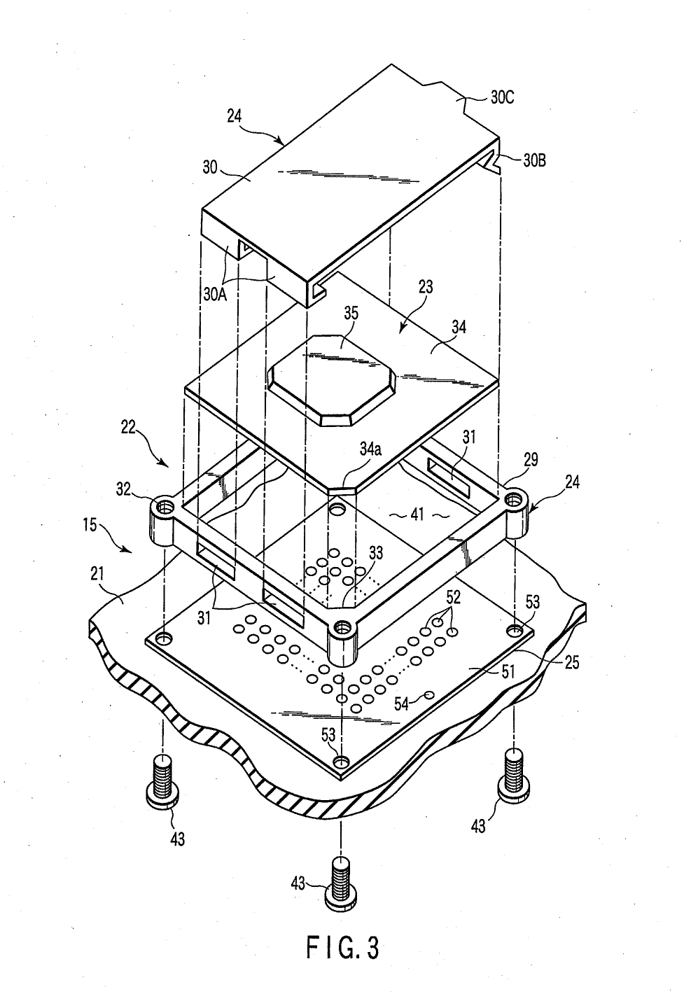

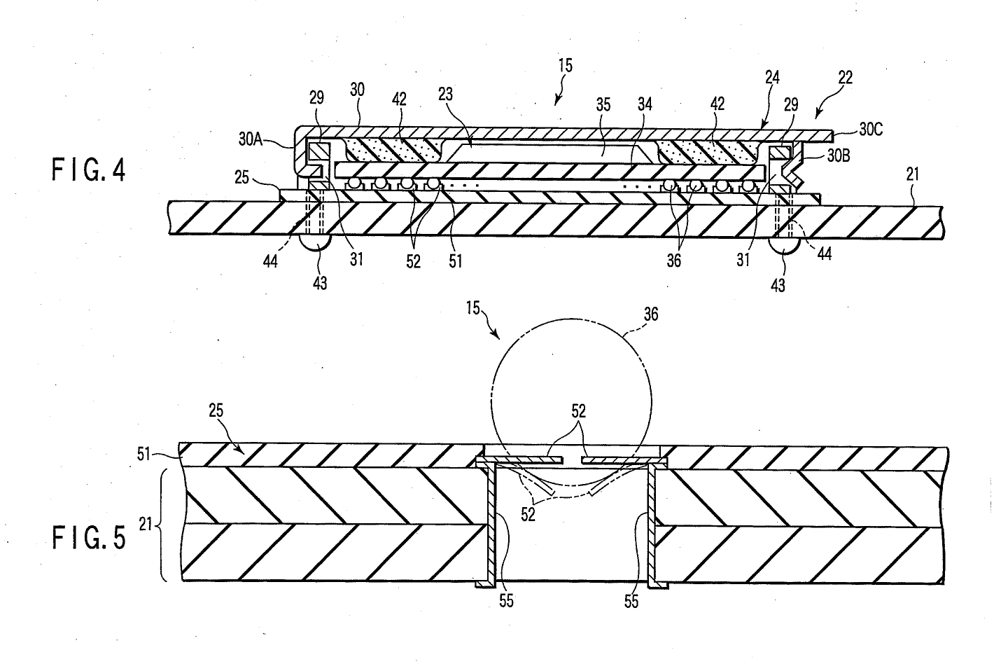

As can be seen from FIG. 3, the frame member 29 includes a bulge portion 33 located at the front portion thereof for positioning the semiconductor package 23. The semiconductor package 23 includes a substrate 34, and a resin mold 35 for containing a semiconductor element. The substrate 34 has a cutout portion 34a having a shape complementary to that of the bulge portion 33. The frame member 29 enables the semiconductor package 23 to be positioned on the printed wiring board 21. As shown in FIG. 4, solder balls 36 are provided in a matrix on the lower surface of the semiconductor package 23.

The lid member 30 covers part of the region 41 surrounded by the frame member 29. The lid member 30 includes a pair of hook portions 30A and joint portions 30B for fixing the lid member 30 to the frame member 29. The hook portions 30A and joint portions 30B are located corresponding to the four lateral holes 31 of the frame member 29. The lid member 30 also includes a projection 30C to be pinched when detaching the member 30.

Further, as shown in FIG. 4, the lid member 30 has an elastic member 42 for urging the semiconductor package 23 against the flexible substrate 25. The elastic member 42 has a frame shape that enables the member 42 to be urged against the substrate 34 of the semiconductor package 23, avoiding the resin mold 35 of the package. In the embodiment, a heat conductive sheet (not shown) may be attached to the portion of the lid member 30 that is brought into contact with the resin mold 35 of the package 23. Alternatively, a heat conductive grease may be provided instead of the heat conductive sheet. Further, the lid member 30 may be formed of a copper member of a high heat conductivity. These can further enhance the heat releasing property of the semiconductor package 23.

The printed wiring board 21 is formed of, for example, a copper laminated plate in which copper wiring layers are stacked. As shown in FIG. 4, the printed wiring board 21 has engagement holes 44 through which screw members 43 are inserted to screw the socket unit 24.

As shown in FIGS. 4 and 5, the flexible substrate 25 comprises a substrate main body 51 and a plurality of connection terminals 52 that connect the semiconductor package 23 to the printed wiring board 21. The connection terminals 52 are arranged in a matrix in accordance with the solder balls 36. The substrate main unit 51 is formed of a polyimide film with a thickness of several microns to several tens microns. As can be seen from FIG. 3, the substrate main body 51 is a square member with through holes 53 provided in the four corners thereof and inserting the screw members 43 therethrough. Further, a pair of holes 54 are formed in the substrate main body 51 for positioning the semiconductor package 23. The semiconductor package 23 has projections (not shown) at locations corresponding to the holes 54.

As shown in FIG. 5, the connection terminals 52 are flexible members. In this embodiment, the connection terminals 52 are flexible plate members each having, for example, a cross-shaped slit formed in the central portion thereof. The edges of each connection terminal 52 are soldered to, for example, through-hole plating 55 or a pad (not shown) on the printed wiring board 21.

When the semiconductor package 23 is placed on the flexible substrate 25 and the solder balls 36 are brought into contact with the connection terminals 52, the central portion of each connection terminal 52 is angled toward the printed wiring board 21 as indicated by the two-dot chain lines in FIG. 5. In this state, the central portion of each connection terminal 52 serves as a plate spring and supports the corresponding solder ball 36. In this state, the solder balls 36 are electrically connected to the connection terminals 52.

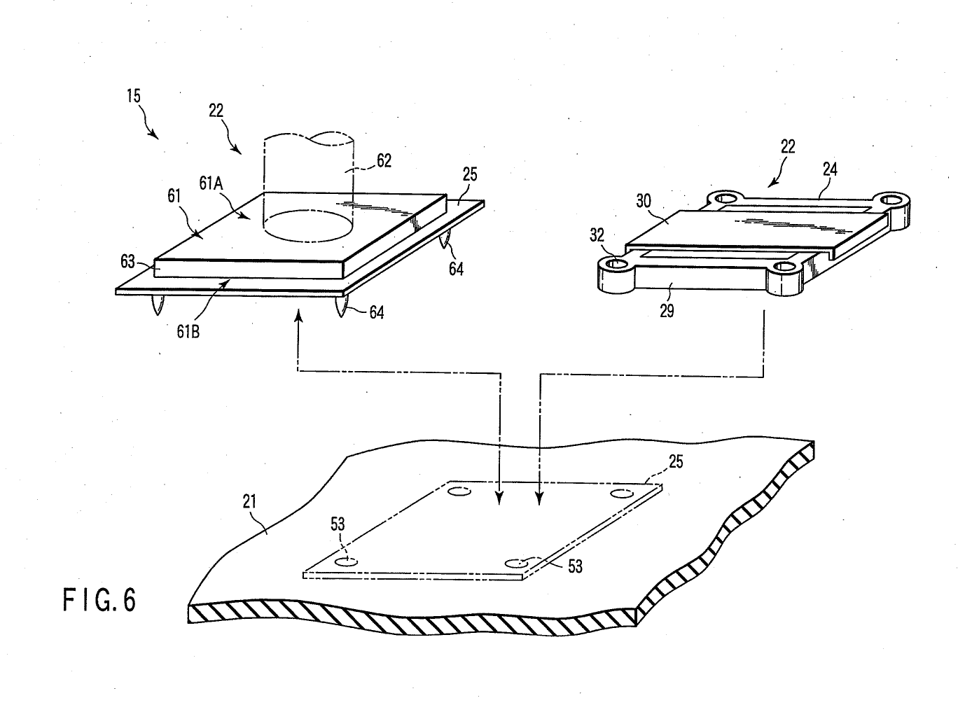

Referring now to FIGS. 6 to 8, a description will be given of the procedure of mounting the semiconductor package 23, to which the component-fixing method of the invention is applied. The semiconductor package 23 is mounted using the flexible substrate 25, a positioning member 61 for positioning the flexible substrate 25 on the printed wiring board 21, and the socket unit 24 for fixing the semiconductor package 23. Before describing the mounting operation of the semiconductor package 23, the positioning member 61 will be described. The positioning member 61 is incorporated in the component-fixing device 22.

The positioning member 61 has a suction section 61A, and function section 61B provided at the opposite position of the suction section 61A. The suction section 61A can be held by suction by an automatic mounter 62. The suction section 61A enables the automatic mounter 62 to mount the flexible substrate 25 on the printed wiring board 21. The function section 61B has a square thin-plate main body 63 and four pins 64 provided at the four corners of the main body 63. The positioning member 61 is formed of, for example, a metal having a small heat capacity.

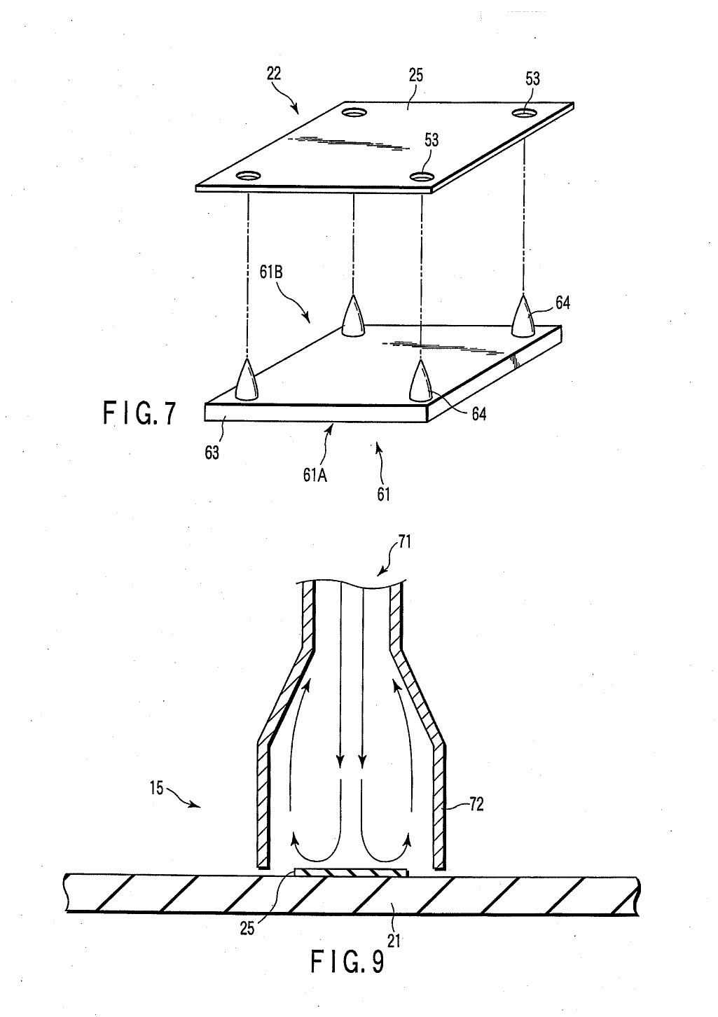

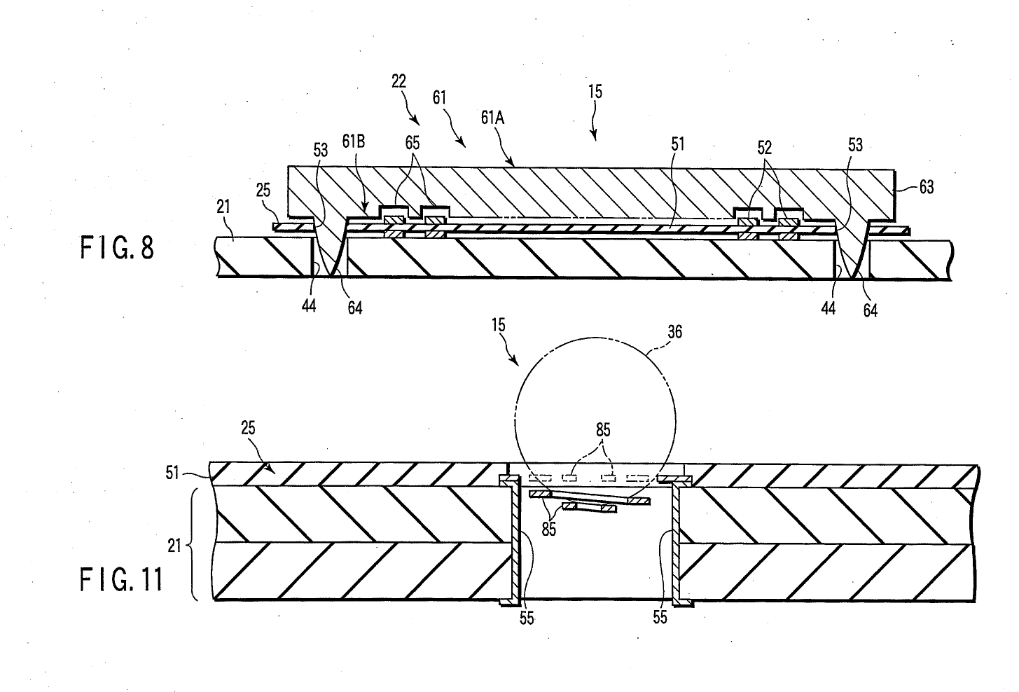

As shown in FIG. 7, the four pins 64 have sharp points. The pins 64 are provided at positions corresponding to the through holes 53 of the flexible substrate 25. The flexible substrate 25 is tightly held by the positioning member 61 with the pins 64 inserted in the through holes 53. The outer diameter of the proximal ends of the pins 64 is larger than that of the through holes 53. Further, as shown in FIG. 8, the function section 61B of the main body 63 is provided with a plurality of depressions 65 arranged in a matrix and corresponding to the connection terminals 52.

As can be seen from FIG. 6, the mounting operation of the semiconductor package 23 starts from the first step of mounting the positioning member 61 with the flexible substrate 25 onto the printed wiring board 21. The positioning member 61 is mounted by, for example, the automatic mounter 62. It is a matter of course that an operator may manually mount the positioning member 61.

When the flexible substrate 25 is mounted, the four pins 64 of the positioning member 61 function as guide members. Namely, the flexible substrate 25 is mounted at the correct position, with the four pins 64 inserted in the four engagement holes 44 of the printed wiring board 21. At this time, the connection terminals 52 of the flexible substrate 25 are aligned with the through-hole plating 55 or pads of the printed wiring board 21.

When the positioning member 61 is mounted on the printed wiring board 21, the mount state as shown in FIG. 8 is acquired. In this state, the function section 61B of the positioning member 61 urges the flexible substrate 25 against the printed wiring board 21. Further, solder is beforehand supplied to the through-hole plating 55 or pads of the printed wiring board 21. The subsequent second step is executed with the flexible substrate 25 urged against the printed wiring board 21 by the positioning member 61. In the second step, the printed wiring board 21 with the flexible substrate 25 mounted thereon is sent to a reflow furnace, where the beforehand supplied solder is melted.

After finishing the second step, the third step of removing the positioning member 61 with the flexible substrate 25 left is executed. In the third step, the socket unit 24 is mounted on the printed wiring board 21 in place of the positioning member 61. The third step is executed as part of a post-process after finishing reflow soldering. The removed positioning member 61 is reused. The positioning member 61 may be removed by suction by the automatic mounter 62.

The mounting operation of the socket unit 24 is started from the mounting of the frame member 29 on the printed wiring board 21 by screwing. The frame member 29 is reliably screwed to the printed wiring board 21 with the flexible substrate 25 interposed therebetween.

After finishing the third step, the fourth step of mounting the semiconductor package 23 is executed. In the fourth step, the semiconductor package 23 is mounted on the region 41 surrounded by the frame member 29 of the socket unit 24. The semiconductor package 23 is directly mounted on the flexible substrate 25. At this time, the positioning of the socket unit 24 with respect to the printed wiring board 21 and flexible substrate 25 is performed using the engagement holes 44 of the printed wiring board 21 and the screw members 43. Further, the alignment of the solder balls 36 of the semiconductor package 23 with the connection terminals 52 of the flexible substrate 25 is performed, using the frame member 29, and the pair of holes 54 of the flexible substrate 25. Specifically, the orientation of fixing of the semiconductor package 23 is determined by the bulge portion 33 of the semiconductor package 23, and the cutout portion 34a of the substrate 34.

The lid member 30 is secured to the frame member 29 containing the semiconductor package 23. Specifically, the hook portions 30A are inserted into the corresponding two lateral holes 31 of the frame member 29, and then the joint portion 30B are inserted into the other two lateral holes 31, thereby securing the lid member 30 to the frame member 29. When the lid member 30 is secured, the semiconductor package 23 is urged against the flexible substrate 25 by the elastic member 42 of the lid member 30. This is the end of the mounting operation of the semiconductor package 23.

Referring then to FIG. 9, a description will be given of the operation of exchanging the flexible substrate 25 for a new one. In the exchanging operation, the solder used in the flexible substrate 25 and printed wiring board 21 is melted using a BGA repair device 71. The BGA repair device 71 has a nozzle 72 and a heat source (not shown), and can supply hot air to the printed wiring board 21.

Where the semiconductor package 23 and socket unit 24 are removed, the solder of the flexible substrate 25 is melted using the BGA repair device 71. After melting the solder, the flexible substrate 25 is removed and a new flexible substrate 25 is mounted. This operation enables the flexible substrate 25 to be exchanged for a new one without adversely influencing the solder coupling of the other structures on the printed wiring board 21.

As described above, in the portable computer 11 of the first embodiment, since the flexible substrate 25 is incorporated in the component-fixing device 22, even if stress occurs in the printed wiring board 21 because of external force, disconnection is prevented from occurring in the connection of the flexible substrate 25 and printed wiring board 21. Further, since the flexible substrate 25 is coupled to the board 21 by solder with the socket unit 24 removed, the heat capacity around the substrate 25 is reduced and hence unsatisfactory melting of the solder can be substantially avoided.

In the portable computer 11 of the first embodiment, since the socket unit 24 and flexible substrate 25 are separate members, the flexible substrate 25 can be exchanged for a new one by the BGA repair device 71, with the socket unit 24 removed. As a result, the heat capacity near the solder coupling portion can be reduced and hence the solder can be melted reliably.

The function section 61B incorporated in the positioning member 61, which is used for coupling the flexible substrate 25 using solder, has the functions of holding the flexible substrate 25, positioning it on the printed wiring board 21, and preventing warpage from occurring in the board 21 in the second step. Accordingly, it is not necessary to provide a plurality of structures for executing the respective functions, which means that the positioning member 61 can be made to have a simple structure. Further, since in the positioning member 61, the main body 63 is formed thin and the depressions 65 are provided at positions corresponding to the connection terminals 52, the positioning member 61 contributes to the reduction of the heat capacity around the solder coupling portions.

The suction section 61A incorporated in the positioning member 61 can be held by the automatic mounter 62. This structure enables the flexible substrate 25 to be mounted on the printed wiring board 21 promptly and reliably, while preventing it from, for example, bending.

The frame member 29 of the socket unit 24 presses the flexible substrate 25 against the printed wiring board 21 through the screws. This prevents the flexible substrate 25 from peeling off the board 21 because of external force. Further, the socket unit 24 can be easily attached and detached.

The lid member 30 incorporated in the socket unit 24 urges the semiconductor package 23 against the flexible substrate 25. This structure prevents disconnection from occurring between the solder balls 36 of the semiconductor package 23 and the connection terminals 52 of the flexible substrate 25 when an external force is applied. The lid member 30 covers part of the region 41 surrounded by the frame member 29. Accordingly, the other part of the region 41 is exposed to the exterior, which prevents degradation of the heat releasing property of the device due to the employment of the socket structure.

The connection terminals 52 of the flexible substrate 25 are elastic. Accordingly, the solder balls 36 of the semiconductor package 23 are elastically supported by the connection terminals 52, which prevents the connection of the semiconductor package 23 and flexible substrate 25 from being damaged by the pressing force of the lid member 30 or external force.

Furthermore, the fixing screw holes of the printed wiring board 21 also serve as the engagement holes 44 engaged with the pins 64 of the positioning member 61. Therefore, it is not necessary to provide a structure dedicated to the positioning of the printed wiring board 21, which simplifies the structure of the printed circuit board 15.

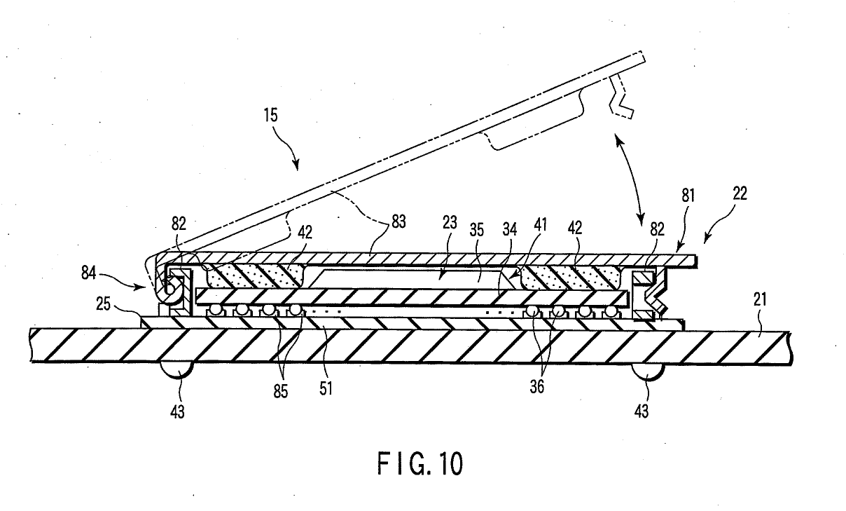

Referring to FIGS. 10 and 11, a description will be given of an electronic apparatus according to a second embodiment, which employs a component-fixing device. The component-fixing device employed in the second embodiment is similar to that of the first embodiment except that the former employs a socket unit 81 and connection terminals 85 (incorporated in the flexible substrate 25). In the first and second embodiments, like reference numbers denote like elements, and no description is given of the like elements.

As shown in FIG. 10, the socket unit 81 of the second embodiment a frame member 82, lid member 83 and a hinge mechanism 84 interposed between the members 82 and 83. The hinge mechanism 84 supports the lid member 83 such that the lid member 83 can be opened and closed with respect to the frame member 29.

As indicated by the broken lines in FIG. 11, the connection terminals 85 of the flexible substrate 25 each have a spiral shape. The edge of each connection terminal 85 is soldered to, for example, through-hole plating 55 or a pad (not shown) on the printed wiring board 21. When the semiconductor package 23 is mounted, the solder balls 36 are brought into contact with the central tips of the spiral connection terminals 85, and push down them as indicated by the solid lines of FIG. 11. Thus, the connection terminals 85 elastically support the solder balls 36. In this state, the connection terminals 85 are electrically connected to the solder balls 36.

In the second embodiment, since the lid member 83 is attached to the frame member 82 via the hinge mechanism 84, the semiconductor package 23 can be easily attached and detached. Further, since the connection terminals 85 elastically support the solder balls 36, the solder coupling portions can be prevented from being damaged, even if the lid member 30 pushes the semiconductor package 23.

The component-fixing device 22 according to the embodiments can be employed not only in the above-described portable computer, but also in other electronic devices such as mobile information terminals.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A component-fixing device comprising:
a flexible substrate including a plurality of connection terminals which connect a circuit component to a printed wiring board;
a positioning member which holds the flexible substrate, positions the flexible substrate on the printed wiring board, and makes the flexible substrate tightly contact the printed wiring board when the flexible substrate is coupled to the printed wiring board, using solder; and
a socket unit secured to the printed wiring board in place of the positioning member, and positions the circuit component on the flexible substrate.

2. The component-fixing device according to claim 1, wherein the positioning member has a suction section allowed to be held by suction by an automatic mounter.

3. The component-fixing device according to claim 1, wherein the socket unit includes a frame member provided at a position opposite to a position of the printed wiring board with respect to the flexible substrate, and screwed to the printed wiring board.

4. The component-fixing device according to claim 3, wherein the socket unit includes a lid member, the lid member covering part of a region surrounded by the frame member and urging the circuit component against the flexible substrate.

5. The component-fixing device according to claim 1, wherein the connection terminals have elasticity.

6. A printed circuit board comprising:
a printed wiring board;
a component-fixing device mounted on the printed wiring board; and
a circuit component mounted on the component-fixing device,
the component-fixing device including:
a flexible substrate including a plurality of connection terminals which connect the circuit component to the printed wiring board;
a positioning member which holds the flexible substrate, positions the flexible substrate on the printed wiring board, and makes the flexible substrate tightly contact the printed wiring board when the flexible substrate is coupled to the printed wiring board, using solder; and
a socket unit secured to the printed wiring board in place of the positioning member, and positions the circuit component on the flexible substrate.

7. The printed circuit board according to claim 6, wherein the printed wiring board includes an engagement hole, the engagement hole being engaged with the positioning member when the flexible substrate is positioned, and receiving a screw when the socket unit is secured.

8. An electronic apparatus comprising a housing and a printed circuit board housed in the housing, wherein:
the printed circuit board includes a printed wiring board, a component-fixing device mounted on the printed wiring board, and a circuit component mounted on the component-fixing device; and
the component-fixing device includes:
a flexible substrate including a plurality of connection terminals which connect the circuit component to the printed wiring board;
a positioning member which holds the flexible substrate, positions the flexible substrate on the printed wiring board, and makes the flexible substrate tightly contact the printed wiring board when the flexible substrate is coupled to the printed wiring board, using solder; and
a socket unit secured to the printed wiring board in place of the positioning member, and positions the circuit component on the flexible substrate.
